(19) United States
(12) Patent Application Publication
(10) Pub. No.: US 2011/0042119 A1
(43) Pub. Date: Feb. 24, 2011

(54) PUMP CHAMBER INTEGRATED LAMPS

(75) Inventor: Robert Battis, Mercerville, NJ (US)

Correspondence Address: FOX ROTHSCHILD LLP;PRINCETON PIKE CORPORATE CENTER, 997 LENOX DRIVE, BLDG. #3, LAWRENCEVILLE, NJ, 08648, US

(73) Assignee: Laser Energetics, Inc.

(21) Appl. No.: 12/866,354

(22) PCT Filed: Feb. 5, 2009
(86) PCT No.: PCT/US09/33278

§ 371 Date: Nov. 15, 2010

Related U.S. Application Data
(60) Provisional application No. 61/026,281, filed on Feb. 5, 2008.

(51) Int. Cl. H05K 5/00

(52) U.S. Cl. 174/50

(57) ABSTRACT

A flash-lamp envelope for a solid state flash lamp pumped laser in which the flash-lamp envelope is an extrusion-shaped optically transparent housing designed to act both as a glass sealing envelope and an optical coupler, efficiently transferring radiation from the flash lamp to a solid lasing rod.

### CROSS REFERENCE TO APPLICATIONS

This application is related to, and claims priority from U.S. Provisional Patent application No. 61/026,281 filed on Feb. 5, 2008, by R. Battis titled “Pump Chamber Integrated Lamps”, the contents of which are hereby incorporated by reference.

### TECHNICAL FIELD

The present invention relates to flash lamps, and more particularly to flash lamps used to pump solid state lasers.

### BACKGROUND ART

In the field of solid state lasers, flash lamps are commonly used to provide the energy to power the laser.

FIG. 1 is a schematic plan view of an exemplary flash lamp pumped solid state laser 10. A typical flash lamp pumped solid state laser 10 includes a flash lamp 12, a laser optical coupler 16, a laser rod 18, a high reflector mirror 20, an optical coupling mirror 24. In typical operation, the flash lamp 12 emits radiation 14 that is fed to or focused on the a laser rod 18 by the laser optical coupler 16. The laser optical coupler 16 may, for instance, be an elliptical mirror having the flash lamp 12 at one foci and the a laser rod 18 at the other foci of the ellipse. The laser optical coupler 16 is typically cooled using external heat fins, air cooling, water cooling or a combination thereof.

The radiation 14 from the flash lamp 12 typically has a broad bandwidth. When coupled into the laser rod 18 in sufficient quantity, the radiation 14 pumps electrons from lower levels to populate higher levels, with subsequent spontaneous photon emission when the electron returns to a lower level. By locating the a laser rod 18 photon emission when the electron returns to a lower level. By locating the a laser rod 18 between two mirrors, any spontaneous photon emission along the axis of the a laser rod 18 bounces back and forth between the mirrors generating stimulated emission 22 at the same wavelength. Each pass through the energized laser rod 18 results in amplification of the stimulated emission 22, termed gain. If the gain exceeds the losses due to imperfect mirrors, any absorption or any other factors, the intensity of the stimulated emission 22 builds and a coherent beam of light is created. By making the optical coupling mirror 24 partially transparent, a controlled percentage of the stimulated emission 22 may be extracted as a coherent beam of light 26.

FIG. 2 is a schematic side view of part of an exemplary prior art solid optical coupler 30. The prior art solid optical coupler 30 in FIG. 2 is an exemplary configuration designed to have two flash lamps 12 and one laser rod 18. The prior art solid optical coupler 30 has a reflecting surface 32, that typically has a nearly elliptical shape. The prior art solid optical coupler 30 also has two flash lamp sized semi-circular grooves 34 and one laser rod sized semi-circular groove 36. A prior art solid optical coupler 30 is typically made of a heat conduction material such as, but not limited to, sapphire or cerium doped quartz.

FIG. 3 is a schematic side view of an exemplary prior art laser cavity 40. The prior art laser cavity 40 has two solid optical couplers 30 that between them retain the two flash lamps 12 and the laser rod 18.

The efficiency of the laser cavity 40, i.e., the ration of output power in the coherent beam of light 26 to the flash lamp 12 power, is dependant on the optical coupling efficiency of the optical couplers 30.

Although the prior art laser cavity 40 is a convenient mechanical arrangement, the efficiency of the cavity may be limited by optical losses, such as, but not limited to, the optical loses as radiation 14 leaves the flash lamp 12 and enters the flash lamp sized semi-circular grooves 34. It is highly desirable to make the coupling of radiation 14 emitted by the flash lamp 12 to the laser rod 18 as efficient as possible.

### SUMMARY OF INVENTION

The present invention is a flash-lamp envelope for a solid state flash lamp pumped laser in which the flash-lamp envelope is an extrusion-shaped optically transparent housing designed to act both as a glass sealing envelope and an optical coupler, efficiently transferring radiation from the flash lamp to a solid lasing rod.

### Technical Problem

The technical problem addressed by the present invention includes the construction of optical couplers for flash lamp pumped lasers that have efficient transfer of radiation from the flash lamp to the lasing rod, are capable of reliable manufacture and capable of being readily assembled into a laser cavity.

### Solution to Problem

The present invention solves the problem by effectively making the flash lamp housing part of the optical coupler, thereby reducing the number of surfaces that radiation from the flash lamp has to traverse before reaching the lasing rod. The reduced number of surfaces improves the efficiency of the flash lamp housing.

### ADVANTAGEOUS EFFECTS OF INVENTION

Advantages of the invention include, but are not limited to, the increased efficiency of laser cavities constructed using the pump chamber integrated optical couplers of the present invention.

These and other features of the invention will be more fully understood by references to the following drawings.

### BRIEF DESCRIPTION OF DRAWINGS

FIG. 1 is a schematic plan view of an exemplary flash lamp pumped solid state laser.

FIG. 2 is a schematic side view of part of an exemplary prior art solid optical coupler

FIG. 4 is a schematic side view of an exemplary pump chamber integrated lamp 50 of the present invention.

FIG. 5 shows a two flash lamp, one laser rod, laser resonant cavity.

FIG. 6 that shows a cross section of a four flash lamp, one laser rod embodiment of a quad chamber integrated lamp laser resonant cavity.

FIG. 7 shows a cross section of a four flash lamp, one laser rod embodiment of a two chamber integrated lamp laser resonant cavity.

FIG. 8 that shows a cross section of a two flash lamp, one laser rod embodiment of a two chamber integrated lamp laser resonant cavity.

FIG. 9 shows a cross section of a four flash lamp, one laser rod embodiment of a four chamber integrated lamp laser resonant cavity.

FIG. 10 shows a cross section of a two flash lamp, one laser rod embodiment of a two chamber integrated lamp laser resonant cavity with coupling elements.

FIG. 11 shows a cross section of a two flash lamp, one laser rod embodiment of a two chamber integrated lamp laser resonant cavity 82 with coupling elements.

FIG. 12 shows a cross section of a four flash lamp, one laser rod embodiment of a four chamber integrated lamp laser resonant cavity with coupling elements.

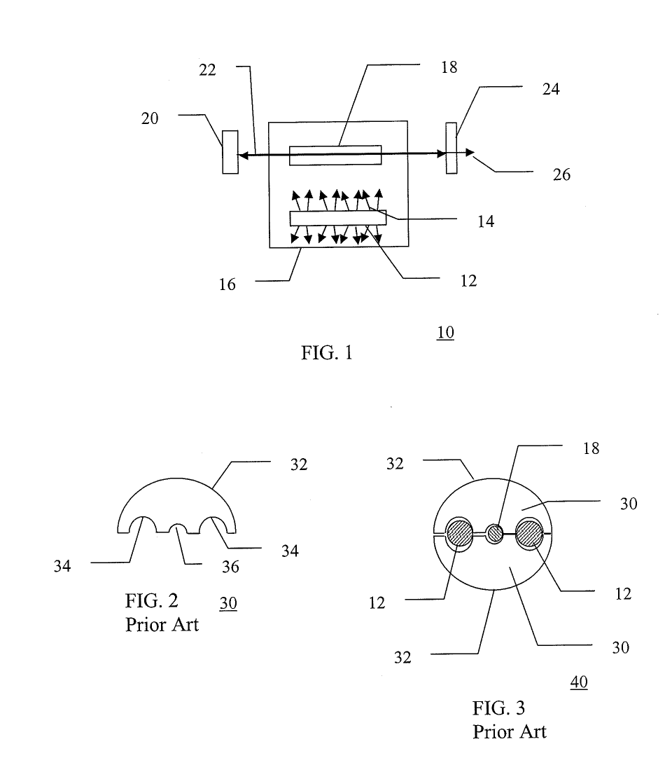

### DESCRIPTION OF EMBODIMENTS

Embodiments of the present invention will now be described in detail by reference to the accompanying drawings in which, as far as possible, like elements are designated by like numbers.

Although every reasonable attempt is made in the accompanying drawings to represent the various elements of the embodiments in relative scale, it is not always possible to do so with the limitations of two-dimensional paper. Accordingly, in order to properly represent the relationships of various features among each other in the depicted embodiments and to properly demonstrate the invention in a reasonably simplified fashion, it is necessary at times to deviate from absolute scale in the attached drawings. However, one of ordinary skill in the art would fully appreciate and acknowledge any such scale deviations as not limiting the enablement of the disclosed embodiments.

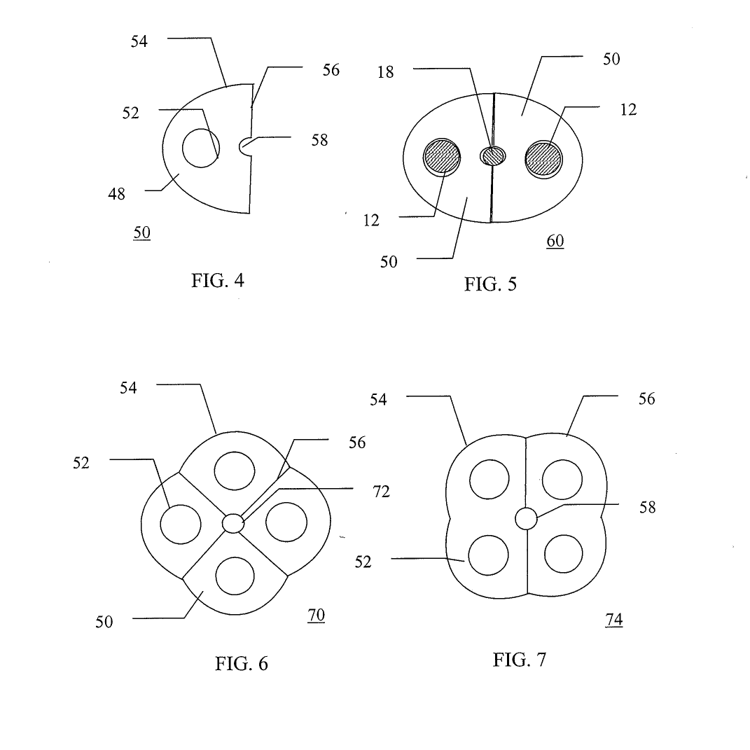

FIG. 4 shows a side view of an exemplary pump chamber integrated lamp 50 of the present invention. The chamber integrated lamp 50 may include a hollow, extrusion-shaped, optically transparent housing 48. An extrusion shape is typically defined as one in which a two dimensional shape is extended along a third dimension that is orthogonal to the plane of the two dimensional shape. The chamber integrated lamp 50 also includes a reflective surface 54, a transparent surface 56, a hollow portion 52 and, optionally a transparent laser rod shaped semi-circle 58. The reflective surface 54 is configured to reflect light emanating from within the hollow portion 52 of the chamber integrated lamp 50. The hollow portion 52 is typically a cylinder and may be designed to directly incorporate a flash lamp filament, a flash lamp gas or electrodes or some combination thereof, so that the extrusion-shaped, optically transparent housing 48 acts both as a glass sealing envelope and an optical coupler. Alternately, the flash lamp 12 may be imbedded in a conventional circular glass sealing envelope that may then be fitted or embedding into the hollow portion 52. The reflective surface 54 may include a metallic or dielectric coating on the surface of the extrusion-shaped, optically transparent housing 48 or it may be a metallic or other foil in close contact. The extrusion-shaped, optically transparent housing 48 may be made of some light transparent, heat conducting material such as, but not limited to, cerium doped quartz or sapphire.

### EXAMPLES

### Example 1

Example 1 of the use of the present invention is illustrated in, for instance, FIG. 5, that shows a two flash lamp 12, one laser rod 18, laser resonant cavity 60 formed of two chamber integrated lamp 50. The reflective surface 54 in such an embodiment may for instance be, but is not limited to, a portion of an ellipse having the center of the hollow portion 52 coincide with one focus of the ellipse, while the center of the laser rod 18 coincides with the other focus of the ellipse.

The laser resonant cavity 60 includes two chamber integrated lamps 50 each of which include a reflective surface 54, a transparent surface 56, a hollow portion 52 and a transparent laser rod shaped semi-circle 58. The reflective surface 54 is configured to reflect light emanating from within the hollow portion 52 of the chamber integrated lamp 50 toward transparent laser rod shaped semi-circle 58.

### Example 2

Example 2 is illustrated in, for instance, FIG. 6 that shows a cross section of a four flash lamp 12, one laser rod 18 embodiment of a quad chamber integrated lamp laser resonant cavity 70.

The quad laser resonant cavity 70 includes four chamber integrated lamps 50 each of which include a reflective surface 54, a transparent surface 56, a hollow portion 52 and a transparent laser rod shaped sector of a circle 72. The reflective surface 54 is configured to reflect light emanating from within the hollow portion 52 of the chamber integrated lamp 50 toward the laser rod shaped sector of a circle 72.

### Example 3

Example 3 is illustrated in, for instance, FIG. 7 that shows a cross section of a four flash lamp 12, one laser rod 18 embodiment of a two laser resonant cavity 74.

The two laser resonant cavity 74 includes two chamber integrated lamps 50 each of which include a reflective surface 54, a transparent surface 56, two hollow portion 52 and a transparent laser rod shaped semi-circle 52. The reflective surface 54 is configured to reflect light emanating from within the hollow portion 52 of the chamber integrated lamp 50 toward the transparent laser rod shaped semi-circle 58.

### Example 4

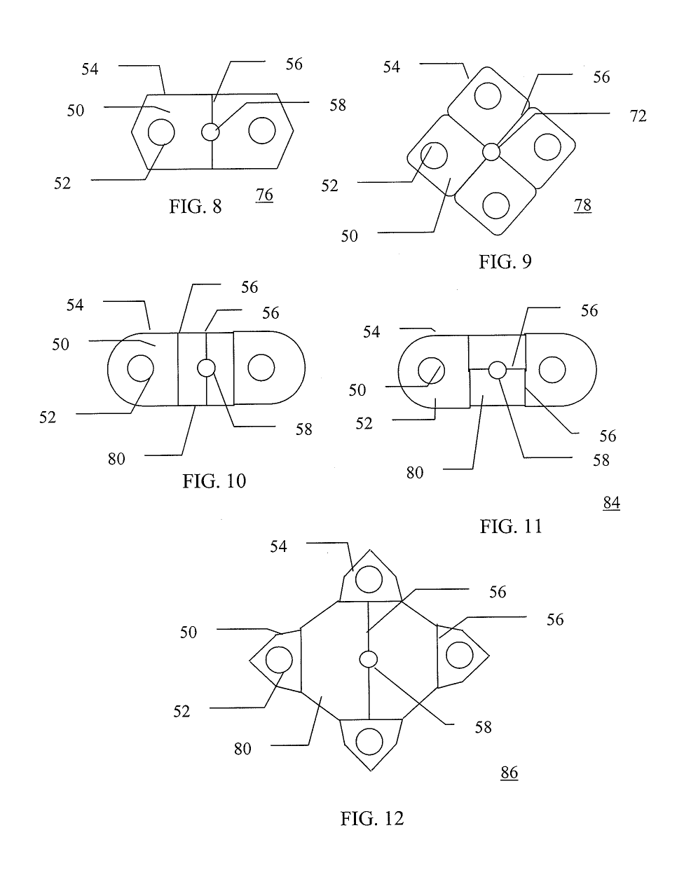

Example 4 is illustrated in, for instance, FIG. 8 that shows a cross section of a two flash lamp 12, one laser rod 18 embodiment of a two chamber integrated lamp laser resonant cavity 76.

The two chamber integrated lamp laser resonant cavity 76 includes two chamber integrated lamps 50 each of which include a reflective surface 54, a transparent surface 56, a hollow portion 52 and a transparent laser rod shaped sector of a circle 72. The reflective surface 54 is configured to reflect light emanating from within the hollow portion 52 of the chamber integrated lamp 50 toward the transparent laser rod shaped sector of a circle 72.

### Example 5

Example 5 is illustrated in, for instance, FIG. 9 that shows a cross section of a four flash lamp 12, one laser rod 18 embodiment of a four chamber integrated lamp laser resonant cavity 78.

The four chamber integrated lamp laser resonant cavity 78 includes four chamber integrated lamps 50 each of which include a reflective surface 54, a transparent surface 56, a hollow portion 52 and a transparent laser rod shaped sector of a circle 72. The reflective surface 54 is configured to reflect light emanating from within the hollow portion 52 of the chamber integrated lamp 50 toward the transparent laser rod shaped sector of a circle 72.

### Example 6

Example 6 is illustrated in, for instance, FIG. 10 that shows a cross section of a two flash lamp 12, one laser rod 18 embodiment of a two chamber integrated lamp laser resonant cavity 82 with coupling elements 80.

The two chamber integrated lamp laser resonant cavity 82 includes two chamber integrated lamps 50 each of which include a reflective surface 54, a transparent surface 56, a hollow portion 52 and two coupling elements 80. The coupling elements 80 include two transparent surfaces 56 and a transparent laser rod shaped semi-circle 58.

An advantage of this embodiment is the relative simplicity of each of the components.

### Example 7

Example 7 is illustrated in, for instance, FIG. 11 that shows a cross section of a two flash lamp 12, one laser rod 18 embodiment of a two chamber integrated lamp laser resonant cavity 82 with coupling elements 80.

The two chamber integrated lamp laser resonant cavity 82 includes two chamber integrated lamps 50 each of which include a reflective surface 54, a transparent surface 56, two hollow portion 52 and two coupling elements 80. The coupling elements 80 include two transparent surfaces 56 and a transparent laser rod shaped semi-circle 58.

An advantage of this embodiment is the relative simplicity of each of the components.

### Example 8

Example 8 is illustrated in, for instance, FIG. 12 that shows a cross section of a four flash lamp 12, one laser rod 18 embodiment of a four chamber integrated lamp laser resonant cavity 82 with coupling elements 80.

The four chamber integrated lamp laser resonant cavity 82 includes four chamber integrated lamps 50 each of which include a reflective surface 54, a transparent surface 56, a hollow portion 52 and two coupling elements 80. The coupling elements 80 include two transparent surfaces 56 and a transparent laser rod shaped semi-circle 58.

An advantage of this embodiment is the relative simplicity of each of the components.

Although the invention has been described in language specific to structural features and/or methodological acts, it is to be understood that the invention defined in the appended claims is not necessarily limited to the specific features or acts described. Rather, the specific features and acts are disclosed as exemplary forms of implementing the claimed invention. Modifications may readily be devised by those ordinarily skilled in the art without departing from the spirit or scope of the present invention.

### INDUSTRIAL APPLICABILITY

In the field of solid state lasers there is significant interest in optical couplers to improve the efficiency of laser. Such an improved optical coupler would be of considerable utility in, for instance, the medical and industrial application of lasers.

1. A flash-lamp envelope, comprising:
a hollow, extrusion-shaped, optically transparent housing having a first surface configured to reflect light emanating from within said hollow portion toward a second, substantially non-reflecting surface.

2. The envelope of claim 1 where in said hollow section of said optically transparent housing is substantially a circular cylinder.

3. The envelope of claim 2 wherein said circular cylinder is configured to incorporate one of a filament, an electrode, a fluorescent gas, or some combination thereof.

4. The envelope of claim 2 wherein said circular cylinder is configured to incorporate a flash lamp envelope.

5. The envelope of claim 1 shaped so that when placed in contact with a substantially identical envelope, a lasing cavity comprising two flash lamps and one lasing rod may be formed.

6. The envelope of claim 1 wherein said hollow section of said optically transparent housing comprises two substantially a circular cylinders and wherein said envelope is shaped so that when placed in contact with a substantially identical envelope, a lasing cavity comprising four flash lamps and one lasing rod may be formed.

7. The envelope of claim 1 shaped so that when placed in contact with a coupling element and a substantially identical envelope also in contact with a coupling element, a lasing cavity comprising two flash lamps and one lasing rod may be formed.

8. The envelope of claim 7 wherein said coupling element comprises a first flat transparent surface and a second transparent surface having a concave semi-circular grove shaped to fit a lasing rod.

9. The envelope of claim 8 wherein said first and second transparent surface are parallel to each other.

10. The envelope of claim 8 wherein said first and second transparent surface are adjacent to each other

11. The envelope of claim 1 shaped so that when four substantially identically shaped envelopes are placed in contact with at least one of two coupling elements, a lasing cavity comprising four flash lamps and one lasing rod may be formed
